(19) United States
(12) Patent Application Publication
(10) Pub. No.: US 2009/0255586 A1
(43) Pub. Date: Oct. 15, 2009

(54) ORGANIC SOLAR CELL AND METHOD OF FABRICATING THE SAME

(75) Inventors: Dong-Yu Kim, Gwangju (KR); Seok-In Na, Gwangju (KR)

Correspondence Address: OCCHIUTI ROHLICEK & TSAO, LLP, 10 FAWCETT STREET, CAMBRIDGE, MA, 02138, US

(73) Assignee: Gwangju Institute of Science and Technology, Gwangju (KR)

(21) Appl. No.: 12/248,309

(22) Filed: Oct. 9, 2008

(30) Foreign Application Priority Data
Apr. 11, 2008 (KR) 10-2008-0033912

(51) Int. Cl. H01L 31/04; B05D 5/12

(52) U.S. Cl. 136/263; 427/74

(57) ABSTRACT

An organic solar cell and a method of fabricating the same are provided. The organic solar cell includes a first electrode and a second electrode. An organic active layer is disposed between the first electrode and the second electrode. The organic active layer includes an concave-convex pattern in a surface adjacent to the second electrode. The concave-convex pattern may be formed by contacting an elastomer stamp and a top surface of the organic active layer. The elastomer stamp may be formed by molding using a template having a surface relief grating (SRG). The template may include a photoisomerization polymer layer, and the surface relief grating may be formed by irradiating interference light onto the photoisomerization polymer layer. The surface relief grating may be a blazed diffraction grating.

### CROSS-REFERENCE TO RELATED APPLICATION

This application claims the benefit of Korean Patent Application No. 2008-0033912, filed Apr. 11, 2008, the disclosure of which is hereby incorporated herein by reference in its entirety.

### BACKGROUND OF THE INVENTION

1. Field of the Invention

The present invention relates to a solar cell, and more particularly, to an organic solar cell.

2. Description of the Related Art

Fossil fuels currently used as a main energy source are gradually decreasing in production. Further, fossil fuels emit carbon dioxide during combustion of the fossil fuel, which contributes to global warming. For this reason, research on conversion technology for environment-friendly energy as a substitute for the fossil fuels is actively progressing. Examples of the environment-friendly energy include hydraulic, wind power, and solar energies.

A solar cell is a device for converting solar light into electrical energy, and most commercial solar cells are fabricated using silicon. However, because of low light absorption of silicon, silicon solar cells are fabricated thick, and equipped outside buildings because of their large size.

To overcome the limitation of such a silicon solar cell, a polymer solar cell using a conjugated polymer is being investigated. While the polymer solar cell absorbs more light than the silicon solar cell, it does not reach a sufficient level yet. A polymer active layer may be formed thick in order to improve the light absorption of the polymer solar cell. However, this increases series resistance.

### SUMMARY OF THE INVENTION

The present invention is directed to an organic solar cell, which does not increase a thickness of an active layer, and greatly improves light absorption, and a method of fabricating the same.

According to an embodiment of the present invention, an organic solar cell is provided. The organic solar cell includes a first electrode and a second electrode. An organic active layer is disposed between the first electrode and the second electrode. The organic active layer includes a concave-convex pattern in one surface adjacent to the second electrode.

The first electrode may be a transparent electrode, and the second electrode may be a reflective electrode. The unevenness may be a diffraction grating, and specifically, a blazed diffraction grating. The organic active layer may be a polymer active layer, and specifically, a bulk heterojunction active layer. A buffer layer may be disposed between the organic active layer and the transparent electrode.

According to another embodiment of the present invention, a method of fabricating an organic solar cell is provided. First, a first electrode is formed on a cell substrate. An organic active layer is formed on the first electrode. An concave-convex pattern is formed in a top surface of the organic active layer. A second electrode is formed on the organic active layer having the concave-convex pattern.

The concave-convex pattern may be formed by contacting an elastomer stamp and the top surface of the organic active layer. The elastomer stamp may be formed by molding using a template having a surface relief grating (SRG). The template may include a photoisomerization polymer layer, and the surface relief grating may be formed by irradiating interference light onto the photoisomerization polymer layer. The surface relief grating may be a blazed diffraction grating.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIGS. 1A to 1D are cross-sectional views illustrating a method of fabricating an organic solar cell according to an exemplary embodiment of the present invention;

FIG. 2 is a cross-sectional view taken along line I-I of FIG. 1D;

FIGS. 3A to 3D are perspective views illustrating a method of molding an elastomer stamp according to an exemplary embodiment of the present invention;

FIG. 4 is a schematic view illustrating a method of forming a surface relief grating according to an exemplary embodiment of the present invention;

FIGS. 5A to 5C are perspective views of various surface relief gratings according to an exemplary embodiment of the present invention;

FIGS. 6A to 6C are AFM photographs of a stamp concave-convex pattern of an elastomer stamp according to Fabrication Example 1, and an organic concave-convex pattern and a surface of a reflective electrode in an organic solar cell according to Fabrication Example 2, respectively;

FIG. 7 is a graph of diffraction order versus diffraction efficiency when light having a wavelength of 325 nm is incident on an interface between an organic active layer and a reflective electrode of an organic solar cell according to Fabrication Example 2 and Comparative Example 1;

FIG. 8 is a graph of voltage versus current density of an organic solar cell according to Fabrication Example 2 and Comparative Examples 1 and 2; and

FIG. 9 is a graph of wavelength of incident light versus incident photon to current conversion efficiency (IPCE) in an organic solar cell according to Fabrication Example 2, and Comparative Examples 1 and 2.

### DETAILED DESCRIPTION OF THE INVENTION

Reference will now be made in detail to the present embodiments of the present invention, examples of which are shown in the accompanying drawings. This invention may, however, be embodied in different forms and should not be construed as limited to the embodiments set forth herein. In the drawings, when a layer is described as being formed on another layer or substrate, the layer may be formed on the other layer or substrate, or a third layer may be interposed between the layer and the other layer or substrate.

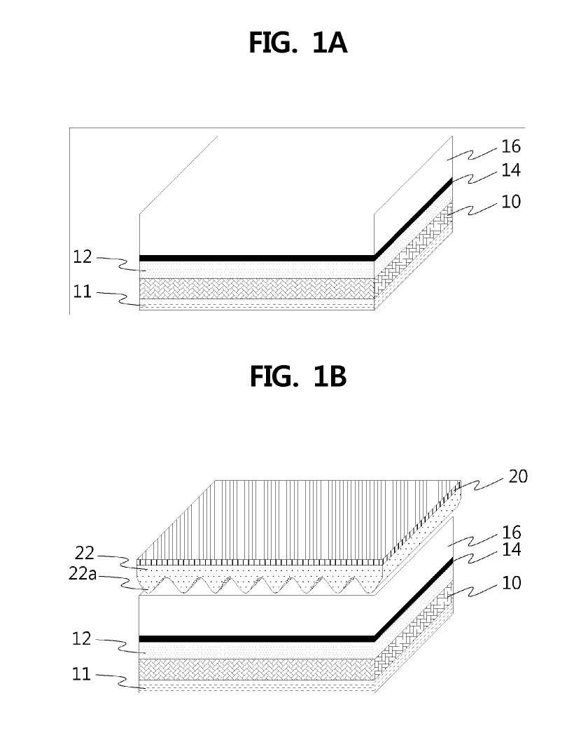

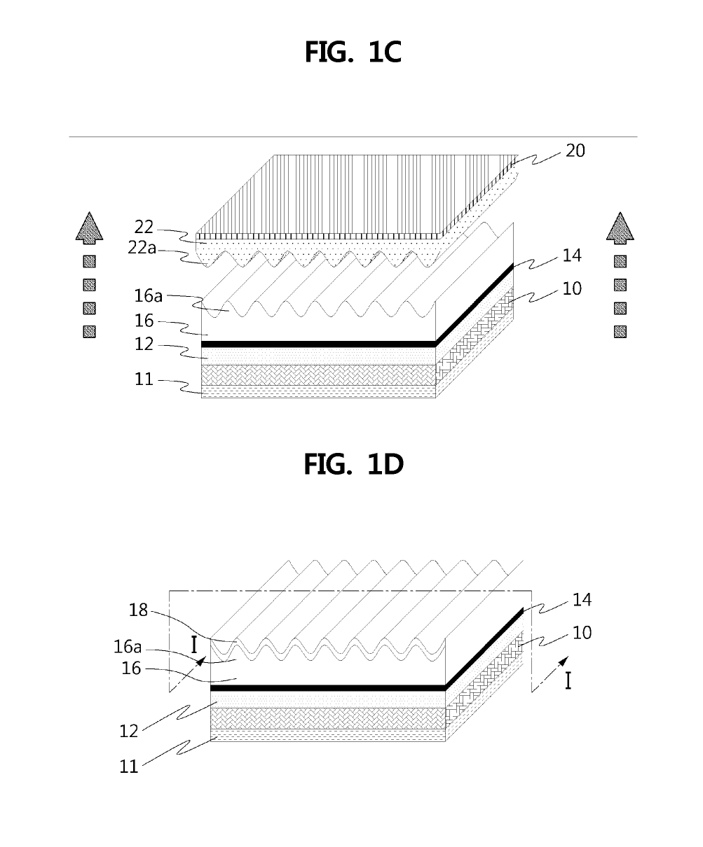

FIGS. 1A to 1D are cross-sectional views illustrating a method of fabricating an organic solar cell according to an exemplary embodiment of the present invention.

Referring to FIG. 1A, a first electrode 12 is formed on a top surface of a cell substrate 10. The cell substrate 10 may be a transparent substrate. The transparent substrate may be a plastic, glass or quartz substrate. The plastic substrate may be formed of polyethylene terephthalate (PET), polyethylene naphthalate (PEN), polyethersulfone (PES) or polyimide (PI).

The first electrode 12 may be a transparent electrode. The transparent electrode may be formed of indium tin oxide (ITO), indium oxide (IO), tin oxide (TO), indium zinc oxide (IZO) or zinc oxide (ZO). The first electrode 12 may be formed by vacuum deposition, sol-gel deposition or metal organic deposition. For example, the first electrode 12 may be formed by RF magnetron sputtering.

Before forming the first electrode 12, an antireflection layer 11 may be formed on a lower surface of the cell substrate 10.

An organic active layer 16 may be formed on the first electrode 12. Before forming the organic active layer 16, a buffer layer 14 may be formed on the first electrode 12. The buffer layer 14 may improve an adhesive strength between the first electrode 12 and the organic active layer 16, and serve as a charge transport layer. The buffer layer 14 may be a poly(3,4-ethylenedioxythiophene) (PEDOT): poly(styrene sulfonate) (PSS) layer.

The organic active layer 16 is a photoelectric conversion layer containing an organic material, which absorbs light and generates excitons. The organic active layer 16 may be a donor/acceptor double layer, in which a donor layer is separated from an acceptor layer, or a bulk-heterojunction (BHJ) layer, in which a donor and an acceptor are mixed. In the structure of the donor/acceptor double layer, an electrode is spaced apart from an interface between the donor layer and the acceptor layer, and thus the excitons generated at the interface may be recombined with each other during transfer to the electrode, which may result in low photoelectric conversion efficiency. However, in the bulk-heterojunction layer, the donor and the acceptor are mixed together in the organic active layer 16, so that an electrode is relatively close to a junction interface between the donor and the acceptor, thus reducing probability of recombination of the exciton. Therefore, when the organic active layer 16 is the bulk-heterojunction layer, the photoelectric conversion efficiency may be improved.

The donor may be an organic monomer such as phthalocyanine, a phthalocyanine derivative, merocyanine or a merocyanine derivative, or a polymer such as poly(phenylenevinylene) (PPV), a PPV derivative, polythiophene or a polythiophene derivative. The PPV derivative may be poly(2-methoxy-5-(2-ethyhexoxy)-1,4-phenylenevinylene) (MEH-PPV) or 2-methoxy-5-(3,7-dimethyloctyloxy)-1,4-phenylenevinylene (MDMO-PPV), and the polythiophene derivative may be poly(3-hexylthiophene) (P3HT) or poly(3-octylthiophene) (P3OT). The acceptor may be fullerene, a fullerene derivative, perylene or a perylene derivative. The fullerene derivative may be phenyl-C61-butyric acid methyl ester (PCBM).

The bulk-heterojunction layer may be MEH-PPV:PCBM, MDMO-PPV:PCBM, P3HT:PCBM or P3OT:PCBM.

Referring to FIG. 1B, an elastomer stamp 22 having a stamp concave-convex pattern 22a is in contact with the organic active layer 16 on a surface adjacent to the organic active layer 16. The elastomer stamp 22 may be supported by a stamp support 20. The elastomer stamp 22 may be a silicon rubber stamp. The silicon rubber may include polyalkylsiloxane acid, and specifically, polydimethylsiloxane (PDMS) or polydiethylsiloxane.

The stamp concave-convex pattern 22a may be a linear one-dimensional or island-shaped two-dimensional diffraction grating, and preferably, a blazed diffraction grating structure.

Referring to FIG. 1C, the organic active layer 16 in contact with the elastomer stamp 22 is annealed. As a result, an organic concave-convex pattern 16a corresponding to the stamp concave-convex pattern 22a is formed in a top surface of the organic active layer 16. After that, the elastomer stamp 22 is separated from the organic active layer 16. Thus, since the organic concave-convex pattern 16a is formed using the elastomer stamp 20, which is smooth, not by wet etching, damage to the organic active layer 16 may be reduced.

The organic concave-convex pattern 16a may correspond to the stamp concave-convex pattern 20a to form a linear one-dimensional or island-shaped two-dimensional diffraction grating, and preferably, a blazed diffraction grating structure.

Referring to FIG. 1D, a second electrode 18 is formed on the organic active layer 16 having the organic concave-convex pattern 16a. The second electrode 18 may be a reflective electrode. The reflective electrode may be a double layer of calcium having a low work function and aluminum having good conductivity.

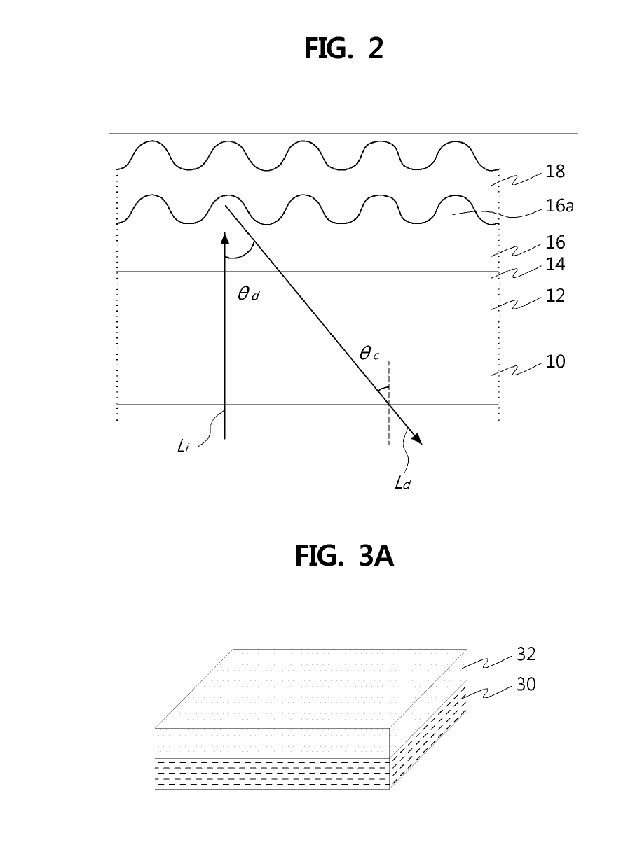

FIG. 2 is a cross-sectional view of an organic solar cell according to an exemplary embodiment of the present invention, which is taken along line I-I of FIG. 1D. However, an antireflection layer of FIG. 1D is omitted.

Referring to FIG. 2, solar light (Li) is incident on a lower surface of the cell substrate 10. The incident solar light (Li) is reflected at an interface between the organic concave-convex pattern 16a and the second electrode 18 and emitted as reflective light (Ld). The organic concave-convex pattern 16a scatters the reflective light (Ld). Accordingly, a light path in which the reflective light (Ld) passes through the organic active layer 16 is increased, thus increasing light absorption of the organic active layer 16. Preferably, the organic concave-convex pattern 16a may be a diffraction grating having a regular concave-convex pattern. Such a diffraction grating may be reconstructed compared to a simple concave-convex pattern. To be specific, the organic concave-convex pattern 16a may be a linear one-dimensional or island-shaped two-dimensional diffraction grating, and preferably, a blazed diffraction grating structure usually generating at least 1st order diffracted light without generating zero order light. Since the at least 1st order diffracted light may have a longer optical path than the incident light, the light absorption of the organic active layer 16 may be increased.

When the organic concave-convex pattern 16a is a diffraction grating, a diffraction equation for the reflective light (Ld) will be given by Formula 1.

mλ=n_{active}·P(sin θᵢ+sin θ_{d})

In Formula 1, m is a diffraction order, λ is a wavelength of incident light, n_{active} is a refractive index of an organic active layer, P is a period of an organic concave-convex pattern, θ₁ is an incident angle, and θ_{d} is a diffraction angle.

Further, the reflective light (Ld) reflected at the interface between the organic concave-convex pattern 16a and the second electrode 18 is not emitted into air, and a condition for total reflection at an interface between the cell substrate 10 and the external air will be given by Formula 2.

$$sin {θ}_{c} > \frac{{n}_{air}}{{n}_{active}} \qquad [ Formula 2 ]$$

In Formula 2, θ_{c} is an incident angle when light reflected from an interface between an organic concave-convex pattern and a second electrode is incident to an interface between a cell substrate and air, n_{active} is a refractive index of an organic active layer, and nₐᵢᵣ is a refractive index of air.

When the light (Li) is incident to the solar cell in a vertical direction, sin θᵢ may be 0 and θ_{c} may be the same as θ_{d}. In this case, under the condition given by Formula 3, the light (Ld) reflected from the interface between the organic concave-convex pattern 16a and the second electrode 18 may be totally reflected at the interface between the cell substrate 10 and the air, and then incident to the organic active layer 16. Thus, a path of the light passing through the organic active layer 16 may be increased, which results in improved light absorption.

$$\frac{m λ}{P} > 1 \qquad [ Formula 3 ]$$

In Formula 3, m is a diffraction order, λ is a wavelength of incident light, and P is a period of an organic concave-convex pattern.

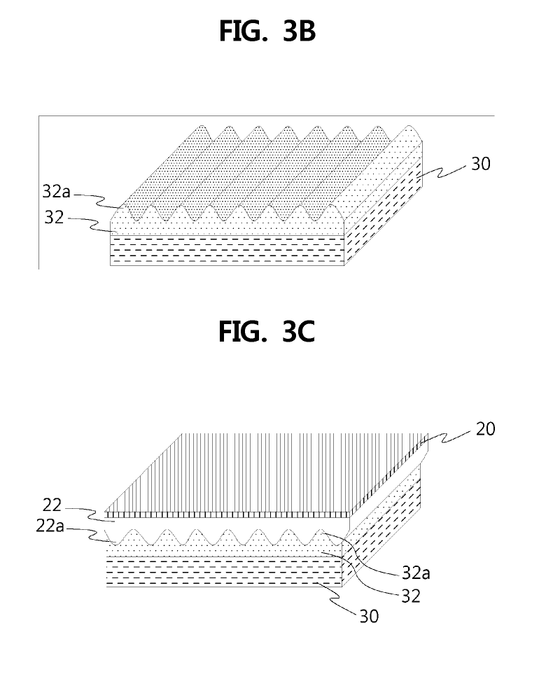

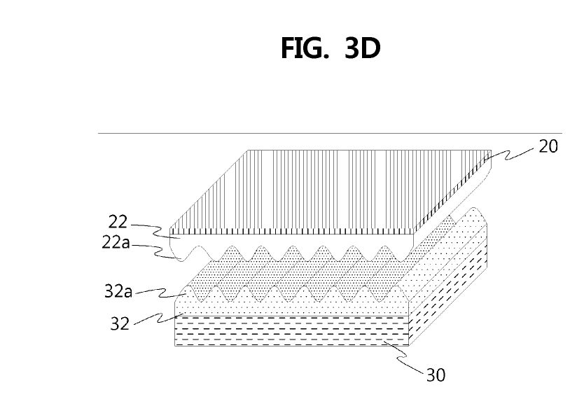

FIGS. 3A to 3D are perspective views illustrating a method of molding an elastomer stamp according to an exemplary embodiment of the present invention.

Referring to FIG. 3A, a photoisomerization polymer layer 32 is formed on a template substrate 30. The photoisomerization polymer layer 32 may be a polymer layer having an azo group. The azo group may be an azobenzene group, and the polymer having the azobenzene group may be poly(disperse orange 3) (PDO3).

Referring to FIG. 3B, a surface relief grating 32a is formed in a top surface of the photoisomerization polymer layer 32.

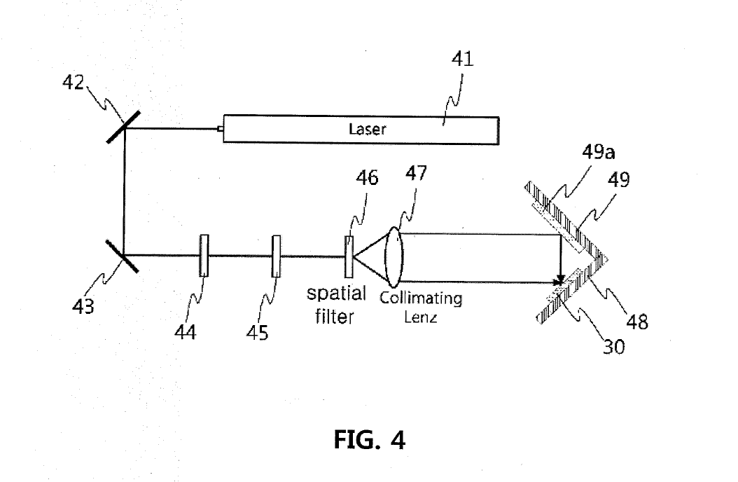

A method of forming the surface relief grating will be described with reference to FIG. 4. Referring to FIG. 4, an optical device for forming a surface relief grating may include a laser source 41, reflection mirrors 42 and 43, a polarizer 44, a wave plate 45, a spatial filter 46, a collimating lens 47, a sample support 48 and a mirror support 49. One of the polarizer 44 and the wave plate 45 may be omitted. The template substrate 30 having the photoisomerization polymer layer 32 (FIG. 3A) is disposed on the sample support 48. A mirror 49a is disposed on the mirror support 49 to generate an interference figure. An angle between the sample support 48 and the mirror support 49 may be approximately 90 degrees.

The laser source 41 may be a laser source generating light having a wavelength of about 400 to 500 nm, for example, an argon laser source. Light emitted from the laser source 41 is reflected from the reflection mirrors 42 and 43 and incident to the polarizer 44 or the wave plate 45, which polarizes the light. After that, the polarized light is converted into collimated light while passing through the spatial filter 46 and the collimating lens 47. After that, a part of the collimated and polarized light is directly incident to the photoisomerization polymer layer 32 (FIG. 3A), and the remainder is incident to the photoisomerization polymer layer 32 (FIG. 3A) after being reflected from the mirror 49a. Thus, interference light is generated on the photoisomerization polymer layer 32 (FIG. 3A), and the surface relief grating 32a (FIG. 3B) is formed by the interference light. Here, the photoisomerization polymer of the photoisomerization polymer layer 32 (FIG. 3A) may absorb light to be cis-trans isomerized. The isomerization may induce the transport of a material due to the interference light, and thus the surface relief grating 32a (FIG. 3B) may be formed.

The period of the surface relief grating 32a (FIG. 3B) may satisfy the following formula.

nλ=2d sin θ [Formula 4]

In Formula 4, n is an integer, λ is a wavelength of a laser source, d is a period of a surface relief grating, and θ is an incident angle of light incident to a photoisomerization polymer layer.

The method of forming the surface relief grating 32a (FIG. 3B) may be a one-step process, which does not require a wet process, and may be reversible in forming a pattern because the pattern may be thermally or optically removed. Further, according to the method, a grating period may be smoothly controlled, and several fine patterns may be overlapped.

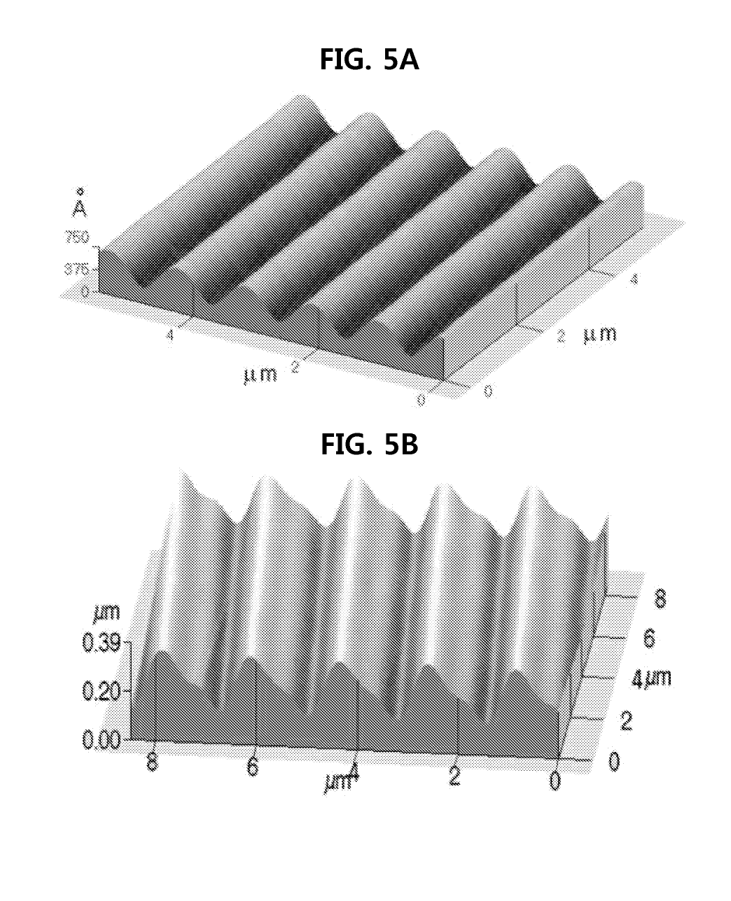

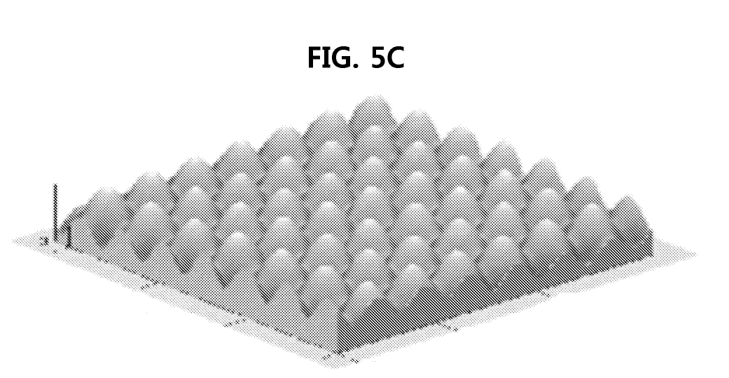

Referring again to FIG. 3B, the surface relief grating 32a may be a linear one-dimensional diffraction grating (FIGS. 5A and 5B) or an island-shaped two-dimensional diffraction grating (FIG. 5C), and preferably, a blazed diffraction grating structure (FIG. 5B) of the linear one-dimensional diffraction grating structures.

Referring to FIG. 3C, an elastomer is molded using the template substrate 30 having the surface relief grating 32a, thereby forming an elastomer stamp 22. The elastomer stamp 22 may be supported by a stamp support 20. A stamp concave-convex pattern 22a corresponding to the surface relief grating 32a may be formed in the elastomer stamp 22.

Referring to FIG. 3D, the elastomer stamp 22 is separated from the template substrate 30.

Hereinafter, preferable examples will be provided to aid in understanding the present invention. However, it will be understood that the examples set forth herein are provided merely to aid in understanding the present invention, and not to limit the present invention.

### EXAMPLES

### Fabrication Example 1

### Fabrication of Elastomer Stamp

A surface relief grating was formed in a top surface of a photoisomerization polymer layer PDO₃ using a 100 mW/cm², 488 nm Argon laser. An elastomer stamp was formed using the PDO3 layer having the surface relief grating as a template. To be specific, the elastomer stamp was formed by pouring a polysiloxane acid prepolymer, which is a 10:1 (wt/wt) mixture of PDMS and a curing agent (Sylgard 184, Dow Corning) on the PDO3 layer having the surface relief grating, curing the polymer at 60□, and then separating the hardened polymer from the PDO3 layer.

### Fabrication Example 2

### Fabrication of Organic Solar Cell

A glass substrate (Samsung Corning) coated with a transparent electrode ITO having a sheet resistance of 10 Ω/sq or less was cleaned, and PEDOT:PSS (Baytron P VPAI 4083, H.C. Starck) was spin-coated to a thickness of 20 nm on the ITO layer. A mixture solution prepared by dissolving 30 mg P3HT (Rieke Metals) and 24 mg PCBM (Nano-C) in 2 ml chlorobenzene was spin-coated on the PEDOT:PSS layer to form an 80 nm organic active layer. The elastomer stamp fabricated in Fabrication Example 1 was conformally disposed on the organic active layer, and annealed for 20 minutes at 110□ in a nitrogen atmosphere, thereby forming an organic concave-convex pattern. After that, the elastomer stamp was separated, and a 20 nm calcium layer and a 100 nm aluminum layer were thermally deposited in sequence in a 10⁻⁶ torr vacuum, thereby forming a reflective electrode.

### Comparative Example 1

### Fabrication of Organic Solar Cell

An organic solar cell was fabricated by the same method as described in Fabrication Example 1, except that an elastomer stamp was not in contact with an organic active layer.

### Comparative Example 2

### Fabrication of Organic Solar Cell

An organic solar cell was fabricated by the same method as described in Fabrication Example 1, except that an elastomer stamp without a stamp concave-convex pattern was formed on an organic active layer.

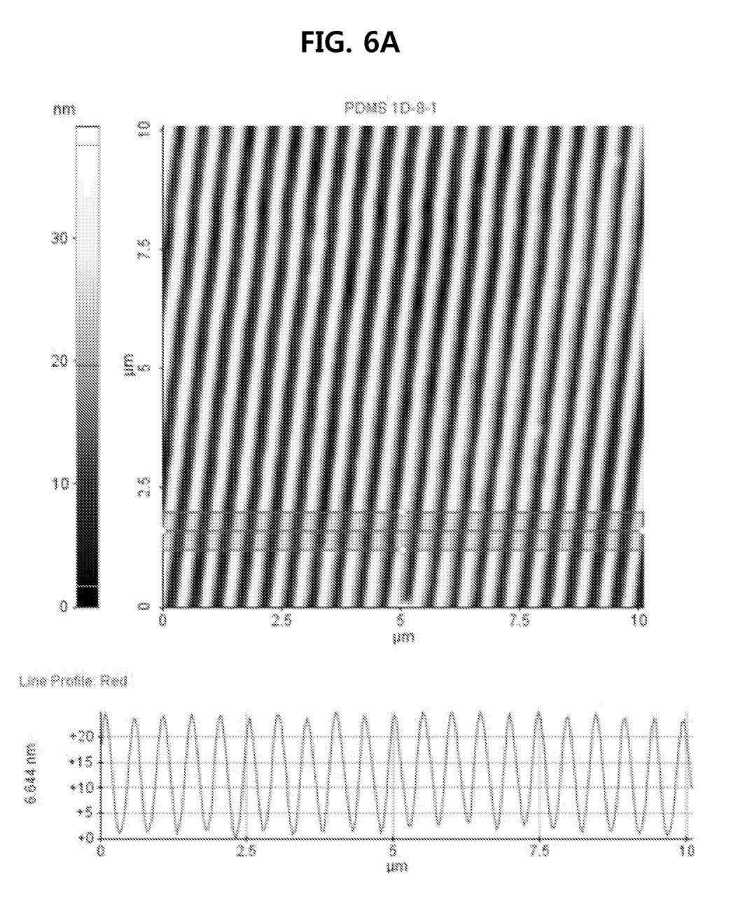

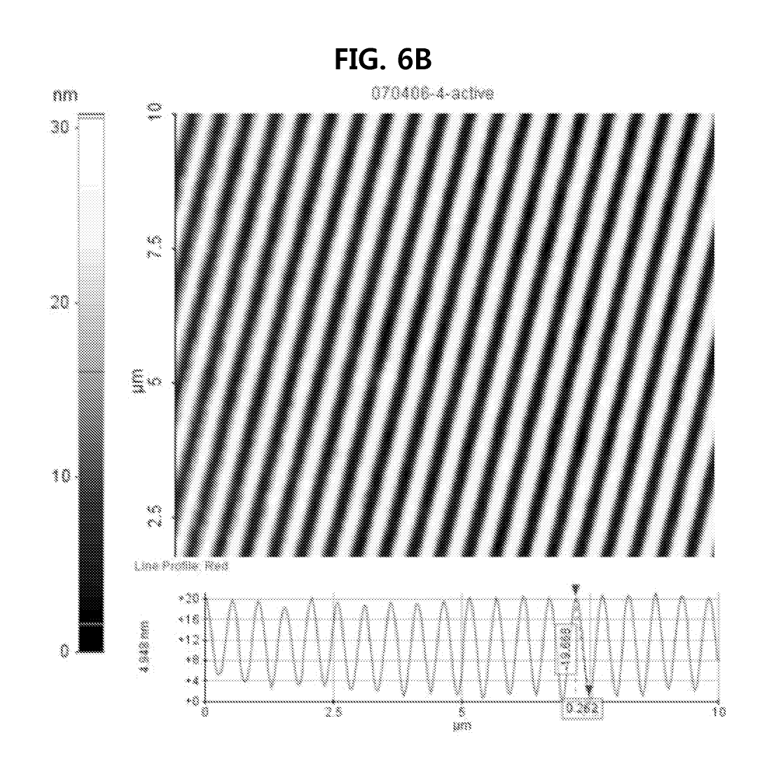

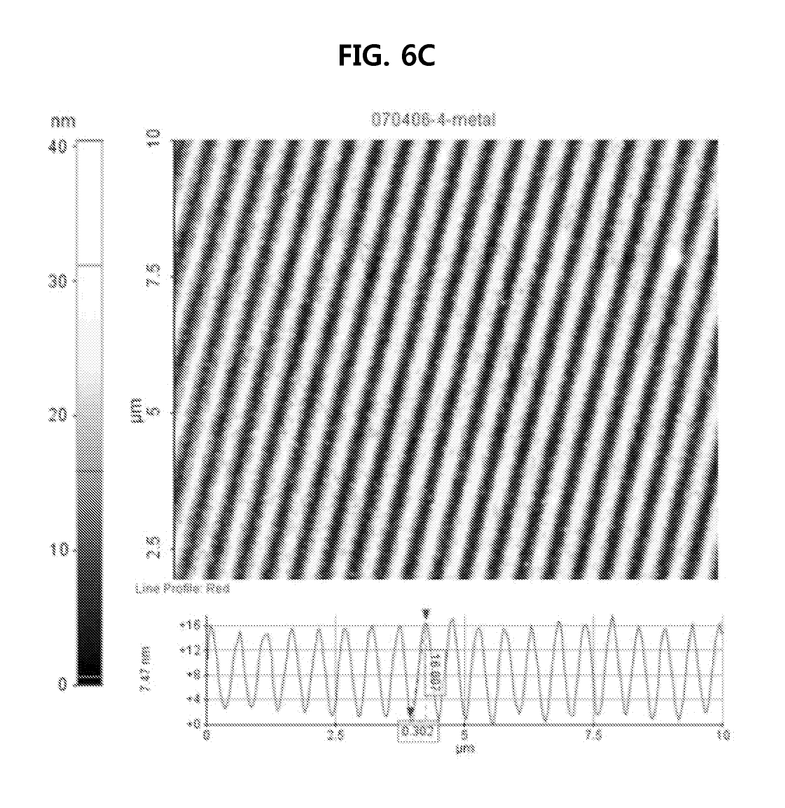

FIGS. 6A to 6C are AFM photographs of a stamp concave-convex pattern of an elastomer stamp according to Fabrication Example 1, and an organic concave-convex pattern and a surface of a reflective electrode in an organic solar cell according to Fabrication Example 2, respectively.

Referring to FIG. 6A, it is found that a stamp concave-convex pattern has a period of 500 nm and a height of 20 nm.

Referring to FIG. 6B, it is found that an organic concave-convex pattern has a period of 500 nm and a height of 20 nm that are substantially the same as the stamp concave-convex pattern.

Referring to FIG. 6C, it is found that a reflective electrode formed along the organic concave-convex pattern also has substantially the same concave-convex pattern as the organic concave-convex pattern.

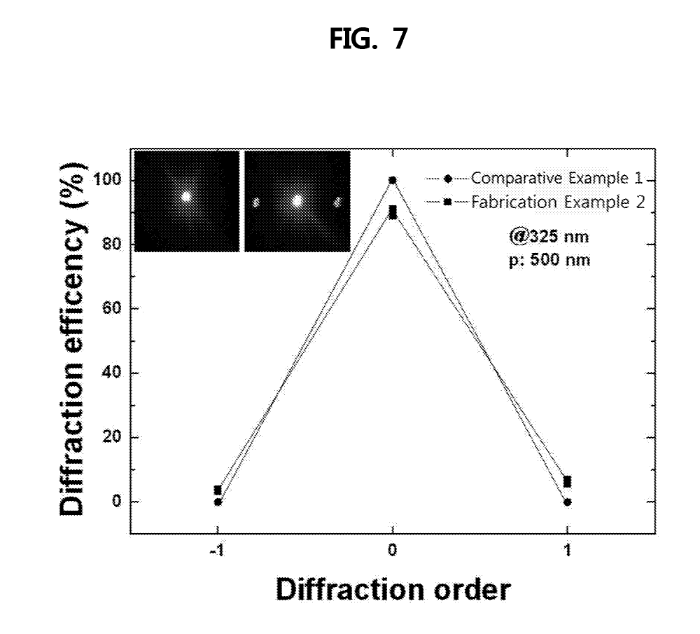

FIG. 7 is a graph of diffraction order versus diffraction efficiency when light having a wavelength of 325 nm is incident to an interface between an organic active layer and a reflective electrode of an organic solar cell according to Fabrication Example 2 and Comparative Example 1.

Referring to FIG. 7, the organic solar cell having the organic concave-convex pattern according to Fabrication Example 2 has higher diffraction efficiency when a diffraction order is ±1, compared to the organic solar cell without the organic concave-convex pattern according to Comparative Example 1. This means that more diffracted light reflected at an interface between a reflective electrode and an organic active layer having an organic concave-convex pattern is capable of diagonally passing through the organic active layer in the organic solar cell according to Fabrication Example 2. Thus, an optical path in the organic active layer may be increased, which results in improved light absorption.

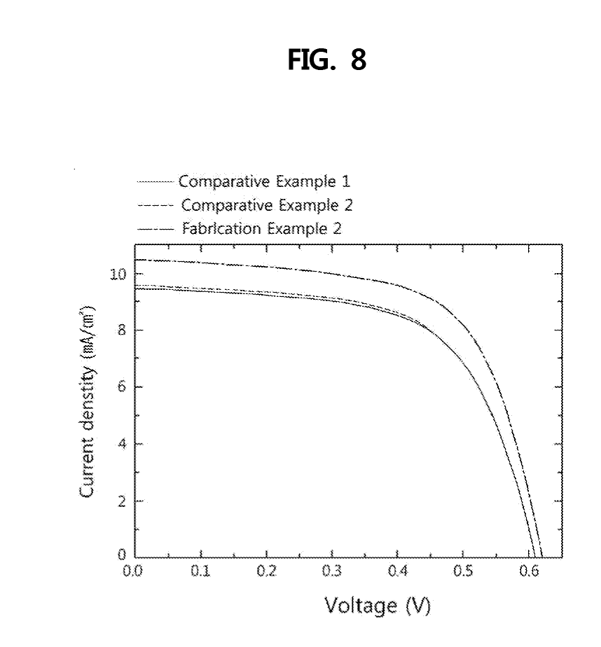

FIG. 8 is a graph of voltage versus current density of organic solar cells according to Fabrication Example 2, and Comparative Examples 1 and 2.

An open circuit voltage (Voc), a short circuit current density (Jsc) and a fill factor (FF) are extracted from FIG. 8 to calculate power conversion efficiency, which is shown in Table 1. In FIG. 8, Voc is a voltage value when current density is 0, Jsc is a current density value when a voltage is 0, and the fill factor is a ratio of maximum power density to a product of Voc and Jsc.

TABLE 1

| | | | | n (%) |
|---|---|---|---|---|
| | | | | (@ input power |
| | | Jsc | | density = |
| | Voc (V) | (mA/cm²) | FF (%) | 100 mW/cm²) |
| F. Example 2 | 0.62 | 10.5 | 63 | 4.11 |
| C. Example 1 | 0.61 | 9.45 | 62 | 3.56 |
| C. Example 2 | 0.61 | 9.57 | 61 | 3.58 |

Referring to FIG. 8 and Table 1, the solar cell having the organic concave-convex pattern in the organic active layer according to Fabrication Example 2 has higher open circuit voltage, short circuit current density, fill factor and power conversion efficiency, compared to the solar cells without the organic concave-convex pattern in the organic active layer according to Comparative Examples 1 and 2.

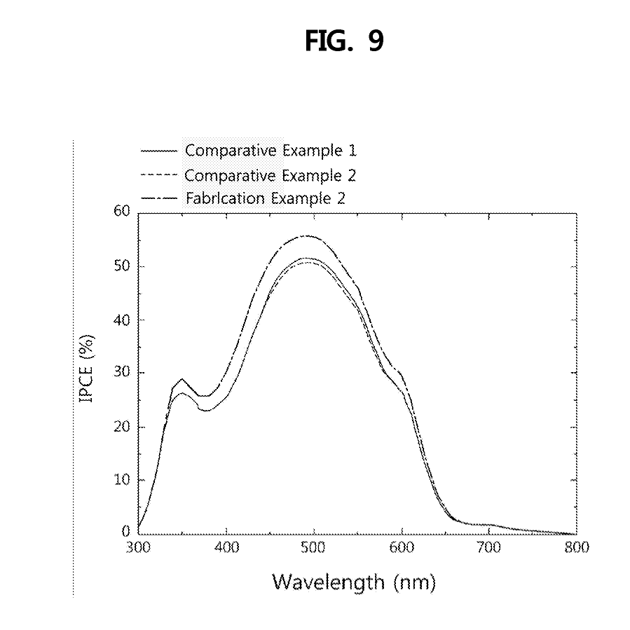

FIG. 9 is a graph of wavelength of incident light versus incident photon to current conversion efficiency (IPCE) of organic solar cells according to Fabrication Example 2, and Comparative Examples 1 and 2.

Referring to FIG. 9, the solar cell having the organic concave-convex pattern in the organic active layer according to Fabrication Example 2 has higher IPCE level in a wide wavelength range, e.g., about 300 to 700 nm, compared to the solar cells without the organic concave-convex pattern in the organic active layer according to Comparative Examples 1 and 2. Also, the organic active layer of the organic solar cell according to Fabrication Example 2 has higher light absorption compared to the organic active layers of the organic solar cells according to Comparative Examples 1 and 2.

According to the present invention, as an organic concave-convex pattern is formed in one surface of an organic active layer, an optical path passing through the organic active layer can be increased, and light absorption can be significantly improved without any change in thickness of the organic active layer. Also, as the organic concave-convex pattern has a blazed diffraction grating structure, the optical path passing through the organic active layer can be further increased.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. An organic solar cell, comprising:
a first electrode;
a second electrode; and
an organic active layer disposed between the first and second electrodes, and comprising a concave-convex pattern formed in a surface adjacent to the second extrude.

2. The cell according to claim 1, wherein the first electrode is a transparent electrode and the second electrode is a reflective electrode.

3. The cell according to claim 1, wherein the concave-convex pattern is a diffraction grating.

4. The cell according to claim 3, wherein the concave-convex pattern is a blazed diffraction grating.

5. The cell according to claim 1, wherein the organic active layer is a polymer active layer.

6. The cell according to claim 5, wherein the polymer active layer is a bulk-heterojunction active layer.

7. The cell according to claim 2, further comprising:
a buffer layer disposed between the organic active layer and the transparent electrode.

8. A method of fabricating an organic solar cell, comprising the steps of:
forming a first electrode on a cell substrate;
forming an organic active layer on the first electrode;
forming an concave-convex pattern in a top surface of the organic active layer; and
forming a second electrode on the organic active layer comprising the concave-convex pattern.

9. The method according to claim 8, wherein the concave-convex pattern is formed by contacting an elastomer stamp with the top surface of the organic active layer.

10. The method according to claim 9, wherein the elastomer stamp is formed by molding using a template having a surface relief grating (SRG).

11. The method according to claim 10, wherein the template includes a photoisomerization polymer layer, and the surface relief grating is formed by irradiating interference light onto the photoisomerization polymer layer.

12. The method according to claim 11, wherein the surface relief grating is a blazed diffraction grating.
